(19) United States
(12) Patent Application Publication
(10) Pub. No.: US 2024/0377740 A1
(43) Pub. Date: Nov. 14, 2024

(54) POSITIVE TYPE PHOTORESIST COMPOSITION, METHOD OF FORMING PHOTORESIST PATTERN, AND CURED FILM

(71) Applicant: SAMSUNG ELECTRONICS CO., LTD., Suwon-si (KR)

(72) Inventors: Jooyoung Song, Suwon-si (KR); Jonghoon Kim, Suwon-si (KR); Hye-Reun Kim, Suwon-si (KR); Mingi Choi, Suwon-si (KR)

(21) Appl. No.: 18/614,294

(22) Filed: Mar. 22, 2024

(30) Foreign Application Priority Data
May 10, 2023 (KR) 10-2023-0060615

(51) Int. Cl. G03F 7/039; G03F 7/004; G03F 7/09; G03F 7/16

(52) U.S. Cl. CPC G03F 7/0392; G03F 7/0045; G03F 7/094; G03F 7/168

(57) ABSTRACT

Provided are positive type photoresist compositions including a polymer resin, a crosslinking agent, and a photoacid generator, wherein the polymer resin includes a main chain including a linking group decomposable under acidic conditions and a thermally crosslinkable functional group linked to the main chain and the crosslinking agent includes a functional group capable of reacting with the thermally crosslinkable functional group. The photoresist compositions of the present disclosure can be coated multiple times to realize a high-thickness photoresist film.

### CROSS-REFERENCE TO RELATED APPLICATION

This application claims priority to and the benefit of Korean Patent Application No. 10-2023-0060615 filed in the Korean Intellectual Property Office on May 10, 2023, the entire contents of which are incorporated herein by reference.

### BACKGROUND

Due to the development of electronic technology, down-scaling of semiconductor devices is rapidly progressing. Accordingly, there is a demand for a photolithography process that is advantageous for implementing fine patterns. Increased thicknesses of photoresist films can be associated with increased viscosities of the photoresist composition.

### SUMMARY

One aspect of the present disclosure is to implement a high-thickness photoresist film through multiple coatings of a positive type photoresist composition.

A positive type photoresist composition according to one aspect includes a polymer resin, a crosslinking agent, and a photoacid generator, wherein the polymer resin includes a main chain including a linking group decomposable under acidic conditions and a thermally crosslinkable functional group linked to the main chain, and the crosslinking agent includes a functional group capable of reacting with the thermally crosslinkable functional group.

The thermally crosslinkable functional group may be at least one selected from an epoxy group, a hydroxyl group, and a methylol group.

The linking group decomposable under the acid condition may have a ketal structure or a phosphoramidate structure.

The functional group capable of reacting with the thermally crosslinkable functional group may be at least one selected from an amino group, an isocyanate group, an epoxy group, a hydroxyl group, and a carboxy group.

The thermally crosslinkable functional group may be a hydroxyl group, and the functional group capable of reacting with the thermally crosslinkable functional group may be an amino group or an isocyanate group.

The thermally crosslinkable functional group may be an epoxy group, and the functional group capable of reacting with the thermally crosslinkable functional group may be a carboxy group.

The thermally crosslinkable functional group is a methylol group, and the functional group capable of reacting with the thermally crosslinkable functional group may be an amino group or a hydroxyl group.

The polymer resin may have a weight average molecular weight of about 1,000 g/mol to about 50,000 g/mol.

The positive type photoresist composition may further include a solvent.

The positive type photoresist composition may include about 0.5 to about 30 parts by weight of the crosslinking agent, about 5 to about 100 parts by weight of the photoacid generator, and about 100 to about 900 parts by weight of the solvent based on 100 parts by weight of the polymer resin.

The positive type photoresist composition may further include a quencher.

The positive type photoresist composition may have a viscosity of about 100 cp or less.

A method of forming a semiconductor pattern according to an aspect includes a first step of coating a positive type photoresist composition and heating the same; a second step of exposing it; a third step of developing after the exposure, wherein the first step is repeated two or more times.

In the method of forming the semiconductor pattern, the positive type photoresist composition includes a polymer resin, a crosslinking agent, a photoacid generator, a quencher, and a solvent, wherein the polymer resin may include a main chain including a linking group decomposable under acidic conditions and thermally crosslinkable functional group linked to the main chain, the crosslinking agent may include a functional group capable of reacting with the thermally crosslinkable functional group.

The thermally crosslinkable functional group may be at least one selected from an epoxy group, a hydroxyl group, and a methylol group.

The linking group decomposable under the acid condition may have a ketal structure or a phosphoramidate structure.

The functional group capable of reacting with the thermally crosslinkable functional group may be at least one selected from an amino group, an isocyanate group, an epoxy group, a hydroxyl group, and a carboxy group.

The cured film according to one aspect may have a thickness of about 10 μm or more, obtained by coating and heating the positive type photoresist composition two or more times.

The cured film may include Structural Formula 1 or Structural Formula 2 below.

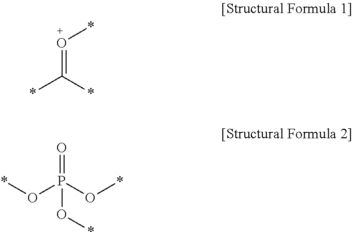

The positive type photoresist composition used in preparing the cured film includes a polymer resin, a crosslinking agent, a photoacid generator, a quencher, and a solvent, and the polymer resin includes a main chain including a linking group decomposable under acidic conditions and thermally crosslinkable functional group linked to the main chain, and the crosslinking agent may include a functional group capable of reacting with the thermally crosslinkable functional group.

Since the positive type photoresist composition according to one aspect has thermal crosslinking properties and is crosslinked when heated after coating, multiple coatings are possible to realize a high-thickness photoresist film.

Furthermore, since the positive type photoresist composition according to one aspect includes a linking group decomposable under acidic conditions in the main chain, upon exposure after coating, the main chain of the polymer resin in the exposed portion is cut and the solubility is increased, so that a semiconductor pattern can be easily implemented.

### BRIEF DESCRIPTION OF THE DRAWINGS

FIG. 1 is a view showing a process of realizing a high-thickness photoresist film by coating a positive type photoresist composition twice according to some implementations of the present disclosure.

FIG. 2 is a view showing a process of realizing a high-thickness photoresist film by coating a positive type photoresist composition three times according to some implementations of the present disclosure.

FIG. 3 is a view showing a process of forming a semiconductor pattern by exposing and developing the high-thickness photoresist film of FIG. 1 according to some implementations of the present disclosure.

FIG. 4 is a view showing a process of forming a semiconductor pattern by exposing and developing the high-thickness photoresist film of FIG. 2 according to some implementations of the present disclosure.

### DETAILED DESCRIPTION

Hereinafter, various implementations of the present disclosure will be described in detail with reference to the accompanying drawings so that those of ordinary skill in the art may easily implement the present disclosure. The present disclosure may be implemented in various different forms and is not limited to the implementations described herein.

The drawings and description are to be regarded as illustrative in nature and not restrictive. Like reference numerals designate like elements throughout the specification.

The size and thickness of each constituent element as shown in the drawings are arbitrarily indicated for better understanding and ease of description, and this disclosure is not necessarily limited to as shown. In the drawings, the thickness of layers, films, panels, regions, etc., are exaggerated for clarity. In addition, in the drawings, for better understanding and ease of description, the thickness of some layers and areas is exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means being disposed on or below the object portion, and does not necessarily mean being disposed on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

In addition, throughout the specification, when referring to “plane”, it means when the target part is viewed from above, and when referring to “cross section”, it means when viewing the cross section of the target portiont vertically cut from the side.

As used herein, when a definition is not otherwise provided, “substituted” refers to replacement of hydrogen by a substituent selected from a halogen atom (F, Cl, Br, or I), a hydroxyl group, a C1 to C20 alkoxy group, a nitro group, a cyano group, an amine group, an imino group, an azido group, an amidino group, a hydrazino group, a hydrazono a group, a carbonyl group, a carbamyl group, a thiol group, an ester group, an ether group, a carboxyl group or a salt thereof, a sulfonic acid group or a salt thereof, pa hosphoric acid or a salt thereof, a C1 to C20 alkyl group, a C2 to C20 alkenyl group, a C2 to C20 alkynyl group, a C6 to C20 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, a C3 to C20 heteroaryl group, or a combination thereof.

In order to increase a thickness of the photoresist film, there is a method of increasing a viscosity of the photoresist composition to be coated or lowering a RPM during spin coating. However, due to the nature of spin coating, RPM cannot be lowered below a certain level for coating thickness uniformity. As a result, there is almost no method for increasing a thickness of the photoresist film except for increasing the viscosity of the photoresist composition. However, the higher the viscosity of the photoresist composition, the lower the coating processibility of the composition. Since pumping is no longer possible when the viscosity of the composition rises above a certain level, there is a need for a technique for realizing a high-thickness photoresist film through spin coating without increasing the viscosity of the photoresist composition. Therefore, this disclosure provides a low-viscosity photoresist composition including a polymer resin, a crosslinking agent and a photoacid generator, and modification of a structure of the functional group of the polymer resin and the crosslinking agent and the main chain of the polymer resin, and thereby it is well crosslinked under heating conditions and the crosslinked film quality is not easily washed away even when exposed to a solvent later, to enable coating the photoresist composition multiple times, and to enable realization of a high-thickness photoresist film quality without increasing the viscosity of the composition. Furthermore, through the modification, the main chain of the polymer resin is easily decomposed under acidic conditions, and the molecular weight of the polymer resin is lowered, which greatly increases the solubility in the developer, and ultimately pattern formation using a difference in solubility between the exposed portion and the unexposed portion can be achieved very easily.

That is, the positive type photoresist composition according to one aspect can be coated multiple times while having a low viscosity, for example, a viscosity of 100 cp or less, so that a final film quality of 10 μm or more can be achieved.

A positive type photoresist composition according to some implementations includes a polymer resin, a crosslinking agent, and a photoacid generator, wherein the polymer resin includes a main chain including a linking group decomposable under acidic conditions and a thermally crosslinkable functional group linked to the main chain and the crosslinking agent includes a functional group capable of reacting with the thermally crosslinkable functional group.

Photoresist compositions are divided into positive type and negative type. In the positive type, a portion that receives light (exposed portion) dissolves in the developer, and in the negative type, the portion that does not receive light (non-exposed portion) dissolves in the developer. They may be selectively used as needed. The photoresist composition according to some implementations may be a positive type photoresist composition in which an exposed portion is dissolved in a developer. The positive type photoresist composition according to some implementations may be a resist for KrF excimer laser (248 nm), a resist for ArF excimer laser (193 nm), a resist for F2 excimer laser (157 nm), or a resist for extreme ultraviolet (EUV) (13.5 nm).

Unlike the negative type photoresist composition, in the case of the positive type photoresist composition, since there is no thermal crosslinking group in the composition constituting the photoresist composition, even if the composition is coated on a substrate or wafer and then heated (soft baking), curing of the composition does not occur well, multiple coatings themselves are impossible (the pre-coated composition is washed away by the solvent in the composition during multiple coatings, and it is impossible to form a thick coating layer through multiple coatings), and therefore, the viscosity of the positive type photoresist composition had to be set very high in order to realize a high-thickness photoresist film. As described above, the higher the viscosity, the higher the thickness of the film can be realized. However, since spraying such as pumping or jetting is not performed smoothly, it can have a great impact on processibility and is disadvantageous in terms of economics. Therefore, instead of increasing the viscosity of the positive type photoresist composition, the present disclosure introduces a thermally crosslinkable functional group into the composition of the positive type photoresist composition, specifically, into the polymer resin. As a result, the coating and heating (soft baking) process of the positive type photoresist composition can be repeatedly performed twice or more (the pre-coated composition is thermally crosslinked, and thus pre-coated composition is not washed off by the solvent in the composition during multiple coatings), and regardless of the viscosity of the composition, it is possible to realize a high-thickness photoresist film through multiple coatings.

For example, the thermally crosslinkable functional group may be at least one selected from an epoxy group, a hydroxyl group, or a methylol group (*—CH₂OH).

A thermal crosslinking reaction of the positive type photoresist composition may proceed by reacting the polymer resin including the thermally crosslinkable functional group with a crosslinking agent under a heating condition. Specifically, the crosslinking agent includes a functional group capable of reacting with a thermally crosslinkable functional group in the polymer resin, and more specifically, the crosslinking agent may include two or more functional groups capable of reacting with the thermally crosslinkable functional group. For example, the crosslinking agent may include a functional group capable of reacting with the thermally crosslinkable functional group at both terminal ends.

For example, the crosslinking agent may be represented by Chemical Formula C-1 or Chemical Formula C-2, but is not necessarily limited thereto.

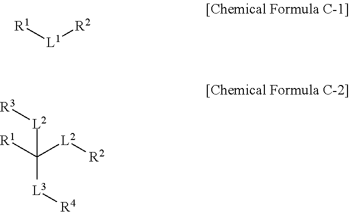

In Chemical Formula C-1 and Chemical Formula C-2,

R¹ to R⁴ are each independently a functional group capable of reacting with a thermally crosslinkable functional group,

L¹ to L³ are each independently a single bond or a substituted or unsubstituted C1 to C20 alkylene group.

For example, the crosslinking agent containing a carboxyl group as a functional group capable of reacting with the thermally crosslinkable functional group at both terminal ends of the crosslinking agent may include suberic acid, glutaric acid, pimelic acid, butane tetracarboxylic acid, etc., but is not necessarily limited thereto.

For example, the crosslinking agent may be included in an amount of about 0.5 parts by weight to about 30 parts by weight based on 100 parts by weight of the polymer resin. If the crosslinking agent is included in an amount of less than about 0.5 parts by weight based on 100 parts by weight of the polymer resin, thermal crosslinking may not be performed smoothly, and, if the crosslinking agent is included in an amount greater than about 30 parts by weight based on 100 parts by weight of the polymer resin, excessive thermal crosslinking may occur to increase the viscosity of the composition too much, which makes it difficult to uniformly coat the composition.

For example, the functional group capable of reacting with the thermally crosslinkable functional group may be at least one selected from an amino group, an isocyanate group, an epoxy group, a hydroxyl group, or a carboxy group.

For example, when the thermally crosslinkable functional group is a hydroxyl group, the functional group capable of reacting with the thermally crosslinkable hydroxyl group may be an amino group or an isocyanate group.

For example, when the thermally crosslinkable functional group is an epoxy group, the functional group capable of reacting with the thermally crosslinkable epoxy group may be a carboxyl group.

For example, when the thermally crosslinkable functional group is a methylol group, the functional group capable of reacting with the thermally crosslinkable methylol group may be an amino group or a hydroxyl group.

When the pairs of the thermally crosslinkable functional group and the functional group capable of reacting therewith are as described above, thermal crosslinking properties may be improved.

For example, the linking group included in the main chain of the polymer resin and decomposable under acidic conditions may have an acid-labile structure, for example, a ketal structure or a phosphoramidate structure, but is not necessarily limited thereto. The ketal structure or phosphoramidate structure may be decomposed according to Reaction Scheme 1 and Reaction Scheme 2 under an acidic condition.

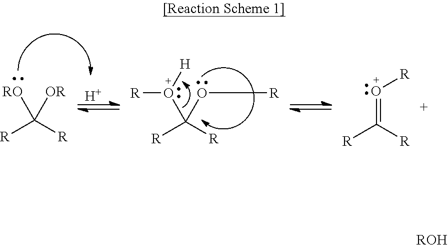

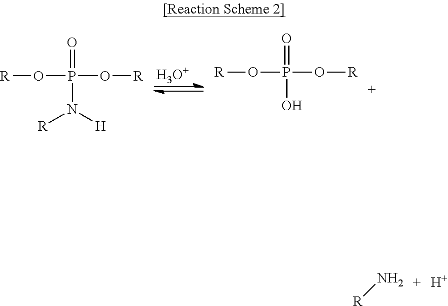

Since the polymer resin contains a linking group decomposable under acidic conditions, the main chain is decomposed as described above by reacting with the acid generated from the photoacid generator at the exposed portion, thereby increasing solubility in the developer and forming a semiconductor pattern well through the developing process.

That is, the positive type photoresist composition according to some implementations has a characteristic in which a main chain decomposition reaction occurs under an acid catalyst, and an acid generated from a photoacid generator through an exposure process reacts with a polymer in the photoresist film to decompose the polymer resin main chain. The exposed portion becomes a chain-scission polymer, so its solubility in the developer is increased, and since the molecular weight of the polymer resin is reduced through chain scission, the solubility of the polymer resin in the developer is further increased. A semiconductor pattern can be very easily implemented using the difference in solubility (to a developer) between the exposed portion and the unexposed portion.

For example, the polymer resin may have a weight average molecular weight of about 1,000 g/mol to about 50,000 g/mol, for example, about 3,000 g/mol to about 30,000 g/mol. When the weight average molecular weight of the polymer resin is within the above range, the main chain decomposition reaction easily occurs under the acidic conditions, and thermal crosslinking can proceed very effectively even under heating conditions because a thermally crosslinkable functional group can be appropriately included.

For example, the photoacid generator may generate an acid when exposed to any one light selected from KrF excimer laser (248 nm), ArF excimer laser (193 nm), F2 excimer laser (157 nm), and EUV laser (13.5 nm). The photoacid generator may be made of a material that generates a relatively strong acid having a pKa (acid dissociation constant) of about −20 or greater and less than about 1 upon exposure to light. The photoacid generator may include, for example, triarylsulfonium salts, diaryliodonium salts, sulfonates, or mixtures thereof. For example, the photoacid generator may be triphenylsulfonium triflate, triphenylsulfonium antimonate, diphenyliodonium triflate, diphenyliodonium antimonate, methoxydiphenyliodonium triflate, di-t-butyldiphenyliodonium triflate, 2,6-dinitrobenzyl sulfonate, pyrogallol tris(alkylsulfonate), N-hydroxysuccinimide triflate, norbornene-dicarboximide-triflate, triphenylsulfonium nonaflate, diphenyliodonium nonaflate, methoxydiphenyliodonium nonaflate, di-t-butyldi Phenyliodonium nonaflate, N-hydroxysuccinimide nonaflate, norbornene-dicarboximide-nonaflate, triphenylsulfonium perfluorobutanesulfonate, triphenylsulfonium perfluorooctanesulfonate (PFOS), diphenyliodonium PFOS, methoxydiphenyliodonium PFOS, di-t-butyldiphenyliodonium triflate, N-hydroxysuccinimide PFOS, norbornene-dicarboximide PFOS, or a mixture thereof.

For example, the photoacid generator may be included in an amount of about 5 parts by weight to about 100 parts by weight based on 100 parts by weight of the polymer resin, but is not necessarily limited thereto.

For example, the positive type photoresist composition may further include a solvent. For example, the solvent may be made of an organic solvent. In some implementations, the solvent may include at least one of ethers, alcohols, glycol ethers, aromatic hydrocarbon compounds, ketones, and esters. For example, the solvent may be selected from ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monomethyl ether acetate, propylene glycol monoethyl ether, propylene glycol monoethyl ether acetate, propylene glycol propyl ether acetate, propylene glycol monobutyl ether, propylene glycol monobutyl ether acetate, toluene, xylene, methyl ethyl ketone, cyclopentanone, cyclohexanone, 2-hydroxyethylpropionate, 2-hydroxy-2-methylethylpropionate, ethoxyethyl acetate, hydroxyethyl acetate, 2-hydroxy-3-methyl methyl butanoate, 3-methoxymethylpropionate, 3-methoxyethylpropionate, 3-ethoxyethylpropionate, 3-ethoxymethylpropionate, methyl pyruvate, ethyl pyruvate, ethyl acetate, butyl acetate, ethyl lactate, butyl lactate, and/or the like. These solvents may be used alone or in combination of at least two. In some implementations, an amount of the solvent in the photoresist composition may be adjusted so that the solid content in the photoresist composition is about 3 wt % to about 20 wt %. The solvent may be included in an amount of about 100 parts by weight to about 900 parts by weight based on 100 parts by weight of the polymer resin.

For example, the positive type photoresist composition may further include a quencher. For example, the quencher may include a base quencher.

The basic quencher may be formed of a compound capable of trapping acid generated from the photoacid generator included in the positive type photoresist composition according to some implementations when the acid is diffused into the unexposed portion of the photoresist film. By including the basic quencher in the photoresist composition according to some implementations, the acid diffusion rate may be suppressed.

For example, the basic quencher may be selected from a primary aliphatic amine, a secondary aliphatic amine, a tertiary aliphatic amine, an aromatic amine, a heterocyclic ring-containing amine, a nitrogen-containing compound having a carboxyl group, a nitrogen-containing compound having a sulfonyl group, a nitrogen-containing compound having a hydroxyl group, a nitrogen-containing compound having a hydroxyphenyl group, an alcoholic nitrogen-containing compound, amides, imides, carbamates, or ammonium salts. For example, the basic quencher may include triethanol amine, triethyl amine, tributyl amine, tripropyl amine, hexamethyl disilazane, aniline, N-methylaniline, N-ethylaniline, N-propylaniline, N,N-dimethylaniline, N,N-bis(hydroxyethyl) aniline, 2-methylaniline, 3-methylaniline, 4-methylaniline, ethylaniline, propylaniline, dimethylaniline, 2,6-diisopropylaniline, trimethylaniline, 2-nitroaniline, 3-nitroaniline, 4-nitroaniline, 2,4-dinitroaniline, 2,6-dinitroaniline, 3,5-dinitroaniline, N,N-dimethyltoluidine, or a combination thereof, but is not necessarily limited thereto.

For example, the basic quencher may be made of a photodegradable base. The photodegradable base may be formed of a compound that generates an acid by exposure and neutralizes the acid before exposure. When the photodegradable base is decomposed by exposure to light, it may lose its function of trapping the acid. Therefore, when a partial region of a photoresist film formed from a photoresist composition containing a basic quencher made of the photodegradable base is exposed to light, the photodegradable base loses alkalinity in the exposed portion of the photoresist film, and in the unexposed portion of the photoresist film, the photodegradable base traps acid to suppress acid diffusion from an exposed portion to a non-exposed portion.

The photodegradable base may include a carboxylate or sulfonate salt of a photodegradable cation. For example, the photodegradable cation may form a complex with an anion of C1 to C20 carboxylic acid. The carboxylic acid may be, for example, formic acid, acetic acid, propionic acid, tartaric acid, succinic acid, cyclohexylcarboxylic acid, benzoic acid, or salicylic acid, but is not necessarily limited thereto.

In the photoresist composition according to some implementations, the quencher may be included in an amount of about 0.01 parts by weight to about 5 parts by weight based on 100 parts by weight of the polymer resin, but is not necessarily limited thereto.

For example, the positive type photoresist composition may further include a surfactant.

For example, the surfactant may be selected from fluoroalkylbenzenesulfonate, fluoroalkylcarboxylate, fluoroalkylpolyoxyethylene ether, fluoroalkylammonium iodide, fluoroalkylbetaine, fluoroalkylsulfonate, diglycerin tetrakis(fluoroalkyl polyoxyethylene ether), fluoroalkyltrimethylammonium salt, fluoroalkylaminosulfonate, polyoxyethylene nonylphenyl ether, polyoxyethylene octylphenyl ether, polyoxyethylene alkyl ether, polyoxyethylene lauryl ether, polyoxyethylene oleyl ether, polyoxyethylene tridecyl ether, polyoxyethylene cetyl ether, polyoxyethylene stearyl ether, polyoxyethylene laurate, polyoxyethylene oleate, polyoxyethylene stearate, polyoxyethylene lauryl amine, sorbitan laurate, sorbitan palmitate, sorbitan stearate, sorbitan oleate, sorbitan fatty acid ester, polyoxyethylene sorbitan laurate, polyoxyethylene sorbitan palmitate, polyoxyethylene sorbitan stearate, polyoxyethylene sorbitan oleate, polyoxyethylene naphthyl ether, alkylbenzene sulfonate, and alkyl diphenyl ether disulfonate, but is not necessarily limited thereto. The surfactant may be included in an amount of about 0.001 part by weight to about 0.1 part by weight based on 100 parts by weight of the polymer resin, but is not necessarily limited thereto.

For example, the positive type photoresist composition may further include a pigment, a preservative, an adhesion promoter, a coating aid, a plasticizer, a surface modifying agent, and/or a dissolution inhibitor.

For example, the positive type photoresist composition may have a viscosity of about 100 cp or less. That is, despite having a low viscosity of about 100 cp or less, the positive type photoresist composition according to some implementations can be coated multiple times, so that a thick photoresist film, for example, a photoresist film having a thickness of about 10 μm or more can be easily implemented.

Hereinafter, an exemplary method of forming a semiconductor pattern according to the technical ideas of the present disclosure will be described with reference to the accompanying drawings.

A method of forming a semiconductor pattern according to an aspect includes a first step of coating a positive type photoresist composition and heating the same; a second step of exposing; and a third step of developing after the exposure, wherein the first step is repeated two or more times.

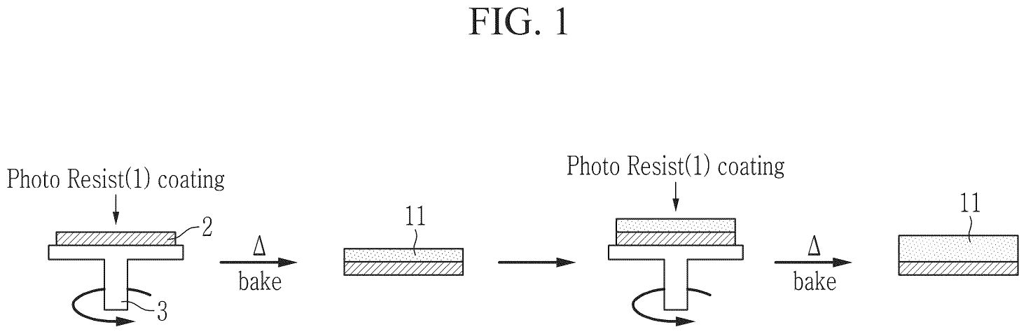

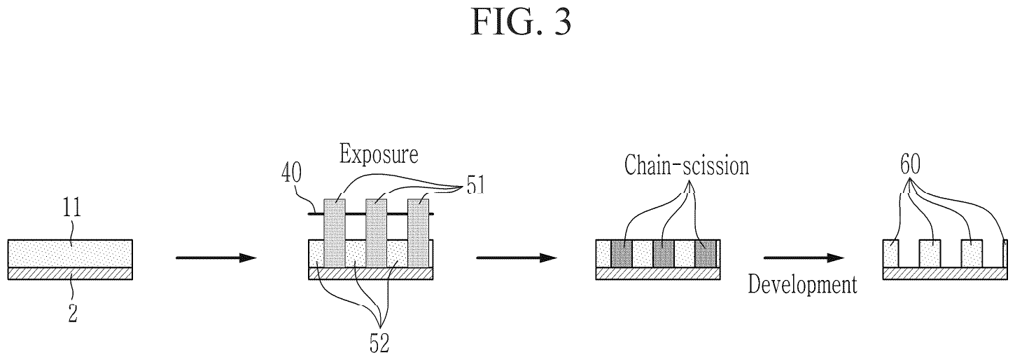

FIG. 1 is a view showing a process of realizing a high-thickness photoresist film by coating a positive type photoresist composition twice, and FIG. 3 shows a process of forming a semiconductor pattern by exposing and developing the high-thickness photoresist film of FIG. 1.

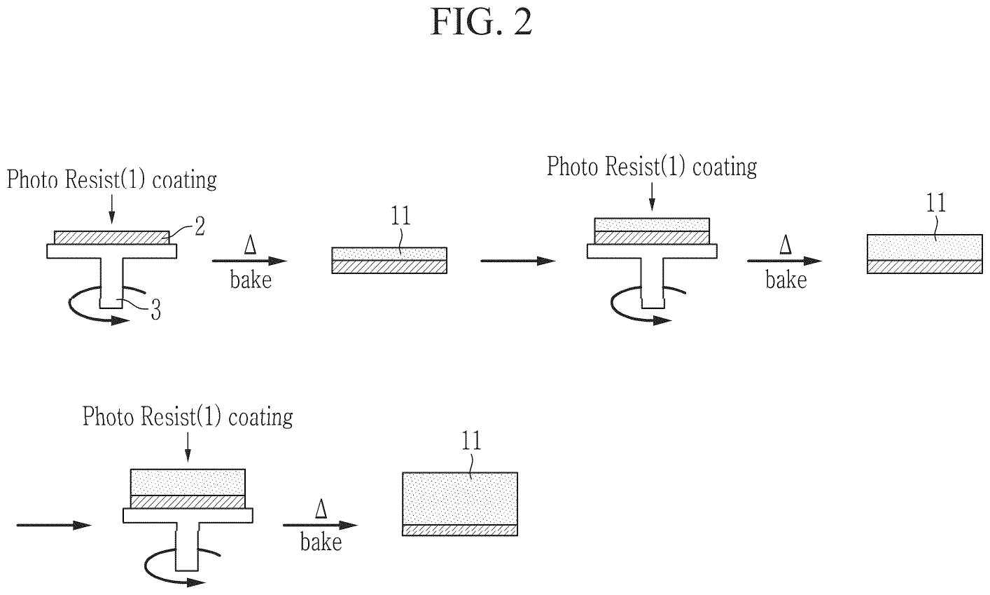

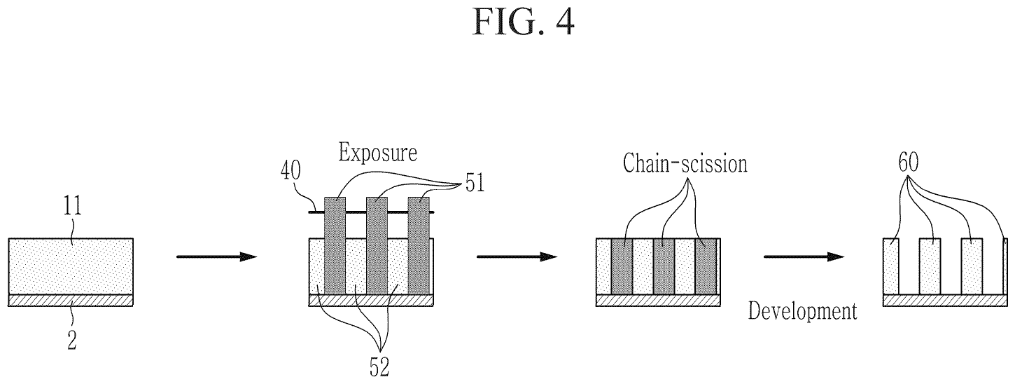

FIG. 2 is a view showing a process of realizing a high-thickness photoresist film by coating a positive type photoresist composition three times and FIG. 4 is a view showing a process of forming a semiconductor pattern by exposing and developing the high-thickness photoresist film of FIG. 2.

Referring to FIGS. 1 and 3, a positive type photoresist composition 1 may be spin-coated on a substrate or wafer 2 and then heated to form a thermally cured film 11, and importantly, such a process may be performed once more. Conventionally, even if a positive type photoresist composition is coated and then heated, thermal curing does not proceed well, so when the positive type photoresist composition is coated once more, most of the photoresist film that had been coated first is washed away by the solvent in the composition, making this multi-coating process itself impossible. However, it is clear that the method of forming a semiconductor pattern according to some implementations is different from some existing methods in that it enables multiple coating of the positive type photoresist composition. The first step of coating the positive type photoresist composition and heating the same is repeated twice to form a thick cured film 11, and then exposing the cured film 11 so that the main chain of the polymer resin in the exposed portion 51 is decomposed by the acid generated from the photoacid generator, and a chain scission reaction of the polymer resin occurs. The polymer resin, whose molecular weight has been lowered through the chain scission reaction, has high solubility in a developer and is washed clean in a developing step, which is a later step, and thus a fine semiconductor pattern can be easily formed.

Referring to FIGS. 2 and 4, a positive type photoresist composition 1 may be spin-coated on a substrate or wafer 2 and then heated to form a thermally cured film 11 and, importantly, this process is performed twice or more. In this example, the first step of coating the positive type photoresist composition and heating it is performed three times to form a thick cured film 11, and then exposing the cured film 11 so that the main chain of the polymer resin in the exposed portion 51 is decomposed by the acid generated from the photoacid generator, and a chain scission reaction of the polymer resin occurs. The polymer resin, whose molecular weight has been lowered through the chain scission reaction, has high solubility in a developer and is washed clean in a developing step, which is a later step, and thus a fine semiconductor pattern can be easily formed.

The coating may be performed by a method such as spin coating, spray coating, or deep coating, and spin coating may be desirable. The process of forming the cured film 11 by heating the positive type photoresist composition may be performed at a temperature of about 80° C. to about 300° C. for about 10 seconds to about 100 seconds, but is not necessarily limited thereto. The cured film 11 may be formed to a thickness of about 10 μm or more, and according to some implementations, the cured film of such a high thickness may be easily formed using a low-viscosity positive type photoresist composition of about 100 cp or less, for example about 90 cp or less, for example about 80 cp or less, for example about 70 cp or less, for example about 60 cp or less, for example, about 50 cp or less, for example, about 40 cp or less, for example, about 30 cp or less, for example, about 20 cp or less, for example, about 10 cp or less.

In order to expose the cured film 11, a photomask 40 having a plurality of light shielding areas LS and a plurality of light transmitting areas LT is placed on the cured film 11 in a predetermined manner, and the cured film 11 may be exposed through the plurality of light transmitting areas LT of the photomask 40. In order to expose the cured film 11, a KrF excimer laser (248 nm), an ArF excimer laser (193 nm), an F2 excimer laser (157 nm), or an EUV laser (13.5 nm) may be used.

The photomask 40 may include a transparent substrate and a plurality of light shielding patterns formed in a plurality of light shielding areas LS on the transparent substrate. The transparent substrate may be made of quartz. The plurality of light shielding patterns may be made of chromium (Cr). The plurality of light transmitting areas LT may be defined by the plurality of light shielding patterns.

For example, an annealing process may be additionally performed to diffuse acids in the exposed portion 51 of the cured film 11. For example, the exposed portion 51 of the cured film 11 is annealed at about 50° C. to about 150° C. to diffuse at least a portion of the acids in the exposed portion 51, so that the acids may be relatively uniformly distributed in the exposed portion 51. The annealing may be performed for about 10 seconds to about 100 seconds. For example, the annealing process may be performed at about 100° C. for about 60 seconds but is not limited thereto.

In some implementations, in order to diffuse the acids in the exposed portion 51 of the cured film 11, a separate annealing process may not be performed. Herein, while the cured film 11 is exposed, the acids may be diffused in the exposed portion 51 of the cured film 11 without the annealing process.

As a result of the acid diffusion in the exposed portion 51 of the cured film 11, the decomposable linking group of the polymer resin main chain constituting the cured film 11 may be easily decomposed under acidic conditions in the exposed portion 51, and the exposed portion 51 of the cured film 11 may be changed into a state of being easily dissolved in a developer and specifically, for example, an alkali developer.

When a quencher is included in the cured film 11, in an unexposed portion 52, the quencher included in the cured film 11 may act as a quenching base that neutralizes the acids undesirably diffused from the exposed portion 51 to the unexposed portion 52.

Referring to FIGS. 3 and 4, a photoresist film 130 may be developed by using a developer to remove the exposed portion 51 of the cured film 11. As a result, a photoresist pattern made of the unexposed portion 52 of the cured film 11, that is, a semiconductor pattern 60, may be formed.

For example, in order to develop the cured film 11, an alkali developer may be used. The alkali developer may be a 2.38 wt % tetramethylammonium hydroxide (TMAH) solution but is not limited thereto.

Between the substrate or wafer and the cured film, a feature layer (not shown) may be additionally included.

The feature layer may be an insulation layer, a conductive layer, or a semiconductor layer. For example, the feature layer may be formed of metals, alloys, metal carbides, metal nitrides, metal oxynitrides, metal oxycarbides, semiconductors, polysilicons, oxides, nitrides, oxynitrides, or a combination thereof, but is not limited thereto.

The substrate 2 may include a semiconductor substrate. For example, the substrate 2 may include a semiconductor material such as Si or Ge or a compound semiconductor material such as SiGe, SiC, GaAs, InAs, or InP.

In this way, since the polymer resin main chain is decomposed by the acids in the exposed portion 51 of the cured film 11, solubility of the exposed portion 51 by the developer may be improved, while the cured film 11 is developed by the developer, clearly removing the exposed portion 51. Accordingly, after developing the cured film 11, a vertical sidewall profile with no residual defects such as footing and the like may be obtained in the semiconductor pattern 60.

In order to form the semiconductor pattern 60, the positive type photoresist composition including a polymer resin, a crosslinking agent, and a photoacid generator may be used. For example, the positive type photoresist composition may further include a solvent and a quencher. Detailed description of the polymer resin, the crosslinking agent, the photoacid generator, the solvent, the quencher, and the positive type photoresist composition including these materials is the same as described above.

According to the method of forming the semiconductor pattern according to some implementations, since solubility in the developer has a larger difference in the exposed portion 51 and the unexposed portion 52 of the cured film 11 having a high thickness, which is obtained by multiple coatings of the photoresist composition according to the technical ideas of the present disclosure, line edge roughness (LER) and line width roughness (LWR) may be reduced in the semiconductor pattern 60 (photoresist pattern) obtained from the cured film 11, providing high pattern reliability. Accordingly, when the semiconductor pattern 60 (photoresist pattern) is used to perform a subsequent process on the feature layer and/or the substrate 2, dimensional accuracy may be improved by precisely controlling critical dimensions of processing regions or patterns to be formed on the feature layer and/or the substrate 2. In addition, a CD (critical dimension) distribution of the patterns formed on the substrate 2 may be uniformly controlled, ultimately improving productivity of a semiconductor device manufacturing process.

The cured film according to one aspect has a thickness of about 10 μm or more, and is obtained by coating and heating the positive type photoresist composition two or more times.

For example, the cured film may include Structural Formula 1 or Structural Formula 2.

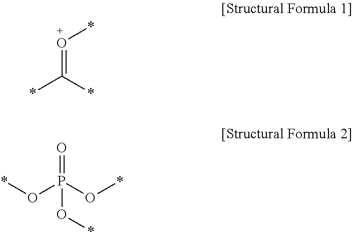

In order to form the photoresist cured film 11 having a thickness of about 10 μm or more, the positive photoresist composition including the polymer resin, the crosslinking agent, and the photoacid generator may be used. For example, the positive type photoresist composition may further include a solvent and a quencher. More details on the polymer resin, crosslinking agent, photoacid generator, solvent, quencher, and positive type photoresist composition including the same are as described above.

Although some implementations have been described above, it is not limited to the examples described above, and various additions, omissions, substituted, and changes may be made. Further, it is possible to form other examples by combining elements in different implementations.

Hereinafter, experiments conducted to evaluate coating uniformity of a cured film formed using a positive type photoresist composition according to some implementations will be described. Experiments described below are merely exemplified to aid understanding of the present disclosure, and the scope of the present disclosure is not limited to the following examples.

### (Preparation of Positive Type Photoresist Compositions)

### EXAMPLES 1 TO 6

Each positive type photoresist composition (viscosity 100 cp or less) was prepared by including 31.5 wt % of a polymer resin (10,000 to 12,000 g/mol), 5 wt % of a crosslinking agent, 6 wt % of a photoacid generator, 0.1 wt % of a quencher, and 57.4 wt % of a solvent. Types of a decomposable linking group in a polymer resin main chain, a thermally crosslinkable functional group linked to the main chain, and a functional group of the crosslinking agent reacting the thermally crosslinkable functional group are shown in Table 1.

TABLE 1

| | Ex. 1 | Ex. 2 | Ex. 3 | Ex. 4 | Ex. 5 | Ex. 6 |
|---|---|---|---|---|---|---|
| Decomposable | ketal structure | phosphoramidate | ketal structure | ketal structure | phosphoramidate | ketal structure |
| linking group | linking group | structure | linking group | linking group | structure | linking group |
| in the main chain | | linking group | | | linking group | |
| Thermally | hydroxyl group | hydroxyl group | epoxy group | n-methylol group | n-methylol group | epoxy group |
| crosslinkable | | | | | | |
| functional group | | | | | | |
| Functional group | amino group | isocyanate group | carboxyl group | amino group | hydroxyl group | amino group |
| capable of reacting | | | | | | |
| with thermally | | | | | | |
| crosslinkable | | | | | | |
| functional group | | | | | | |

### Comparative Examples 1 to 6

Each positive type photoresist composition was prepared in the same manner as in Examples 1 to 6 except that a polybenzoxazole precursor synthesized in the following method was used as the polymer resin. Viscosity thereof was controlled to be 100 cp or less.

### (Synthesis of Polybenzoxazole Precursor)

In a four-necked flask equipped with an agitator, a temperature controller, a nitrogen gas injection device, and a cooler, while passing nitrogen, 11.0 g of bis (3-amino-4-hydroxyphenyl) (phenyl) phosphine oxide was dissolved in 280 g of N-methyl-2-pyrrolidone (NMP). When the solid was completely dissolved, 9.9 g of pyridine was added thereto, and a solution prepared by dissolving 13.3 g of 4,4′-oxydibenzonylchloride in 142 g of N-methyl-2-pyrrolidone (NMP) was slowly added dropwise thereto for 30 minutes, while maintained at 0° C. to 5° C. After the dropwise addition, a reaction was performed at 0° C. to 5° C. for 1 hour and then, completed by increasing the temperature to room temperature and stirring for 1 hour. Herein, 1.6 g of 5-norbornene-2,3-dicarboxyl anhydride was added thereto and then, stirred at 70° C. for 24 hours, completing the reaction. The obtained reaction mixture was added to a solution of water/methanol=10/1 (a volume ratio) to produce precipitates, and the precipitates were filtered, sufficiently washed with water, and dried at 80° C., under vacuum for 24 hours or more, preparing a polybenzoxazole (PBO) precursor having a weight average molecular weight of 11,100 g/mol.

### (Measurement of Average Thickness Coating Uniformity)

Each composition according to Examples 1 to 6 and Comparative Examples 1 to 6 was spin-coated on a substrate, heat-treated at 180° C. in a furnace oven for 50 seconds under a nitrogen stream, and then, once more spin-coated and heat-treated to form cured films, and then, an average thickness and coating uniformity of the cured films were measured, and the results are shown in Table 2. The thickness was measured by using spectroscopic ellipsometry, and the coating uniformity was evaluated by measuring the thickness at 60 points.

TABLE 2

| | Ex. 1 | Ex. 2 | Ex. 3 | Ex. 4 | Ex. 5 | Ex. 6 |
|---|---|---|---|---|---|---|
| Average | 12.0 | 12.1 | 12.0 | 12.0 | 11.9 | 10.3 |
| thickness (μm) | | | | | | |
| Coating | ◯ | ◯ | ◯ | ◯ | ◯ | Δ |
| uniformity | | | | | | |
| | Comp. | Comp. | Comp. | Comp. | Comp. | Comp. |
| | Ex. 1 | Ex. 2 | Ex. 3 | Ex. 4 | Ex. 5 | Ex. 6 |
| Average | 5.1 | 5.2 | 5.1 | 5.1 | 5.2 | 5.2 |
| thickness (μm) | | | | | | |
| Coating | X | X | X | X | X | X |
| uniformity | | | | | | |

### Evaluation Criteria for Coating Uniformity

∘: 0.3 μm or less of a difference between minimum thickness and maximum thickness among thicknesses of each cured film
Δ: greater than 0.3 μm to less than or equal to 0.5 μm of a difference between minimum thickness and maximum thickness among thicknesses of each cured film
X: greater than 0.5 μm of a difference between minimum thickness and maximum thickness among thicknesses of each cured film

As shown in Table 2, the positive type photoresist compositions according to the examples, which were a low viscosity composition including a polymer resin including a thermally crosslinkable functional group and an acid-decomposable linking group in the main chain, compared with low viscosity positive type photoresist compositions according to Comparative Examples 1 to 6, turned out to easily realize a photoresist cured film having a high average thickness of 10 μm through multiple coatings and very excellent coating uniformity during the multiple coatings.

While this disclosure has been described in connection with what is presently considered to be practical implementations, it is to be understood that the claims are not limited to the disclosed implementations, but, on the contrary, is intended to cover various modifications and equivalent arrangements included within the spirit and scope of the appended claims.

What is claimed is:

1. A positive type photoresist composition, comprising:
a polymer resin, a crosslinking agent, and a photoacid generator,
wherein the polymer resin includes a main chain including a linking group decomposable under an acidic condition and a thermally crosslinkable functional group linked to the main chain, and
wherein the crosslinking agent includes a functional group capable of reacting with the thermally crosslinkable functional group.

2. The positive type photoresist composition of claim 1, wherein the thermally crosslinkable functional group comprises at least one of an epoxy group, a hydroxyl group, or a methylol group.

3. The positive type photoresist composition of claim 2, wherein the thermally crosslinkable functional group is the hydroxyl group, and
the functional group capable of reacting with the thermally crosslinkable functional group is an amino group or an isocyanate group.

4. The positive type photoresist composition of claim 2, wherein the thermally crosslinkable functional group is the epoxy group, and
the functional group capable of reacting with the thermally crosslinkable functional group is a carboxyl group.

5. The positive type photoresist composition of claim 2, wherein
the thermally crosslinkable functional group is the methylol group, and
the functional group capable of reacting with the thermally crosslinkable functional group is an amino group or a hydroxyl group.

6. The positive type photoresist composition of claim 1, wherein the linking group decomposable under the acidic condition has a ketal structure or a phosphoramidate structure.

7. The positive type photoresist composition of claim 1, wherein the functional group capable of reacting with the thermally crosslinkable functional group comprises at least one of an amino group, an isocyanate group, an epoxy group, a hydroxyl group, or a carboxy group.

8. The positive type photoresist composition of claim 1, wherein the polymer resin has a weight average molecular weight of 1,000 g/mol to 50,000 g/mol.

9. The positive type photoresist composition of claim 1, wherein the positive type photoresist composition includes a solvent.

10. The positive type photoresist composition of claim 9, wherein the positive type photoresist composition includes, based on 100 parts by weight of the polymer resin,
0.5 to 30 parts by weight of the crosslinking agent,
5 to 100 parts by weight of the photoacid generator, and
100 to 900 parts by weight of the solvent.

11. The positive type photoresist composition of claim 1, wherein the positive type photoresist composition includes a quencher.

12. The positive type photoresist composition of claim 1, wherein the positive type photoresist composition has a viscosity of 100 cp or less.

13. A method of forming a semiconductor pattern, comprising:
coating a substrate with a first layer of a positive type photoresist composition;
heating the first layer of the positive type photoresist composition;
after heating the first layer of the positive type photoresist composition, coating the first layer of the positive type photoresist composition with a second layer of the positive type photoresist composition, to form a combined layer comprising the first layer of the positive type photoresist composition and the second layer of the positive type photoresist composition;
heating the combined layer;
exposing the combined layer; and
developing the combined layer after exposure of the combined layer.

14. The method of claim 13, wherein the positive type photoresist composition includes a polymer resin, a crosslinking agent, a photoacid generator, a quencher, and a solvent,
wherein the polymer resin includes a main chain including a linking group decomposable under an acidic condition and a thermally crosslinkable functional group linked to the main chain, and
wherein the crosslinking agent includes a functional group capable of reacting with the thermally crosslinkable functional group.

15. The method of claim 14, wherein the thermally crosslinkable functional group comprises at least one of an epoxy group, a hydroxyl group, or a methylol group.

16. The method of claim 14, wherein the linking group decomposable under the acid condition has a ketal structure or a phosphoramidate structure.

17. The method of claim 14, wherein the functional group capable of reacting with the thermally crosslinkable functional group comprises at least one of an amino group, an isocyanate group, an epoxy group, a hydroxyl group, or a carboxy group.

18. A cured film obtained by providing multiple stacked layers of a positive type photoresist composition and, after provision of each layer of the multiple stacked layers, heating the layer,
the cured film having a thickness of about 10 μm or more.

19. The cured film of claim 18, wherein the cured film includes Structural Formula 1 or Structural Formula 2:

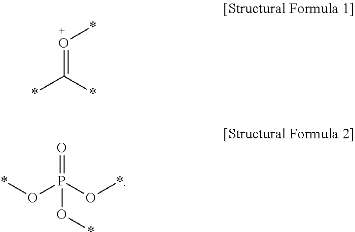

20. The cured film of claim 18, wherein the positive type photoresist composition includes a polymer resin, a crosslinking agent, a photoacid generator, a quencher, and a solvent,
wherein the polymer resin includes a main chain including a linking group decomposable under an acidic condition and a thermally crosslinkable functional group linked to the main chain, and
wherein the crosslinking agent includes a functional group capable of reacting with the thermally crosslinkable functional group.
